(19) United States
(12) Patent Application Publication
(10) Pub. No.: US 2026/0293349 A1
(43) Pub. Date: Sep. 24, 2026

(54) METHODS AND DEVICES FOR INCREASING EFFICIENCY OF IMAGE SENSOR

(71) Applicant: Taiwan Semiconductor Manufacturing Company, LTD., Hsinchu (TW)

(72) Inventors: Ji Heng Jiang, Tainan (TW); Hsin-Yi Kuo, Tainan (TW); Geng-Wei Chang, Taichung (TW); Kun-Yu Lin, Tainan (TW)

(21) Appl. No.: 19/086,265

(22) Filed: Mar. 21, 2025

(51) Int. Cl. H10F 39/00

(52) U.S. Cl. CPC H10F 39/8067; H10F 39/014; H10F 39/811

(57) ABSTRACT

The absorption efficiency of an image sensor is improved by forming a light reflective layer underneath a photodiode. A trench is formed at least partially located to one side of a gate structure. The trench is lined with a high-k adhesive layer, and then filled with a metal to form a light reflector. The trench is then sealed with a barrier layer. The light reflector increases reflectivity towards the photodiode, increasing the quantum efficiency.

### BACKGROUND

Image sensors convert incoming light (photons) into a digital signal for image capture and analysis. This is useful in various applications such as binoculars, cameras (handheld, still, or video), telescopes, and cellphones/smartphones, optical mice for computer input, medical imaging equipment, night vision equipment, and others. Various structures are still being researched to further improve performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a side cross-sectional view showing a first embodiment of the semiconductor device, in accordance with some embodiments of the present disclosure. Here, the light reflector extends into an etch stop layer.

FIG. 1B is a plan view of the semiconductor device through line B-B of FIG. 1A.

FIG. 1C is a side cross-sectional view of a second embodiment of the semiconductor device. Here, the cross-sectional shape of the light reflector is different. The light reflector also has a lower thickness compared to the light reflector of FIG. 1A, and does not extend into the etch stop layer.

FIG. 1D is a side cross-sectional view of a third embodiment of the semiconductor device. Here, the light reflector extends from one side of the gate structure and over the gate structure.

FIG. 1E is a plan view of the semiconductor device of FIG. 1D, illustrating the shape of the light reflector.

FIG. 2 is a flow chart illustrating a method for making a semiconductor device, in accordance with some embodiments.

FIG. 3 is a side cross-sectional view showing the substrate in its initial state.

FIG. 4 is a side cross-sectional view showing the substrate after a anti-reflective coating is formed and a mask is applied.

FIG. 5 is a side cross-sectional view showing the substrate after etching a trench off to one side of the gate structure.

FIG. 6 is a side cross-sectional view showing the substrate after deposition of a high-k dielectric film upon the substrate and the exposed surfaces of the trench.

FIG. 7 is a side cross-sectional view showing the substrate after deposition of a metal to fill the trench and form a light reflector.

FIG. 8 is a side cross-sectional view showing the substrate after planarization to remove the anti-reflective coating and excess material.

FIG. 9 is a side cross-sectional view showing the substrate after deposition of a barrier layer and an interlayer dielectric (ILD) layer upon the substrate.

FIG. 10 is a side cross-sectional view showing the substrate after deposition of a first adhesion layer and formation of a contact trench off to the other side of the gate structure.

FIG. 11 is a side cross-sectional view showing a first embodiment of an image sensor, in accordance with some embodiments of the present disclosure. The semiconductor device of FIG. 1A is indicated here as the M0 layer.

FIG. 12 is a flow chart illustrating a method for making an image sensor, in accordance with some embodiments.

FIG. 13 is a side cross-sectional view showing a portion of the substrate after formation of an interconnect layer and an adhesion layer upon the first side of the substrate.

FIG. 14 is a side cross-sectional view showing a larger portion of the substrate. The substrate has been attached to a carrier wafer and flipped so the second side of the substrate is now exposed for processing. An STI pad is formed in a scribe line region of the substrate.

FIG. 15 is a cross-sectional view of the substrate after forming a silicon layer upon the second side of the substrate (or thickening the substrate), and formation of one or more photodiodes in the substrate.

FIG. 16 is a cross-sectional view of the substrate after forming light focusing structures and deep trench isolation (DTI) regions.

FIG. 17 is a cross-sectional view of the substrate after applying a high-k film upon the second side of the substrate.

FIG. 18 is a cross-sectional view of the substrate after forming a second dielectric layer upon the high-k film.

FIG. 19 is a cross-sectional view of the substrate after etching, deposition of a light absorption layer and a buffer layer, and etching to form light-guiding structures over the DTI regions and to expose the second dielectric layer over the STI pad.

FIG. 20 is a cross-sectional view of the substrate after etching a first trench down to the STI pad.

FIG. 21 is a cross-sectional view of the substrate after etching a second trench down to the interconnect layer.

FIG. 22 is a plan view of another embodiment of an image sensor, in accordance with some embodiments of the present disclosure. Here, multiple photodiodes share a common floating node.

FIG. 23 is a flow chart illustrating a method for using an image sensor, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number. When different ranges are provided, ranges made up of any combination of the two endpoints are also disclosed, with each endpoint being disclosed as either a starting endpoint or an ending endpoint.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example all layers of the structure can be considered to be “on” the substrate, even though they do not all directly contact the substrate. The term “directly” may be used to indicate two layers directly contact each other without any layers in between them. In addition, when referring to performing process steps to the substrate or upon the substrate, this should be construed as performing such steps to whatever layers may be present on the substrate as well, depending on the context.

The present disclosure relates to methods and structures that are particularly useful in semiconductor devices, such as image sensors, for various applications. The image sensor may be, for example, an active-pixel sensor (CMOS sensor). Incoming light signals of a particular wavelength (visible, UV, X-ray, charged particles, etc.) are converted to an electrical signal (usually electrons) and collected/stored in a photodiode. The electrical signal is then read, for example by converting the charge to a voltage signal. Light absorption in the near-infrared (NIR) wavelength range, especially in the range of about 800 nm to about 1000 nm, may be insufficient and affect the performance of the photodiode/image sensor. In the present disclosure, a light reflector is constructed behind or below the photodiode. This permits light which misses the photodiode to be reflected back towards the photodiode, increasing the quantum efficiency of the photodiode/image sensor.

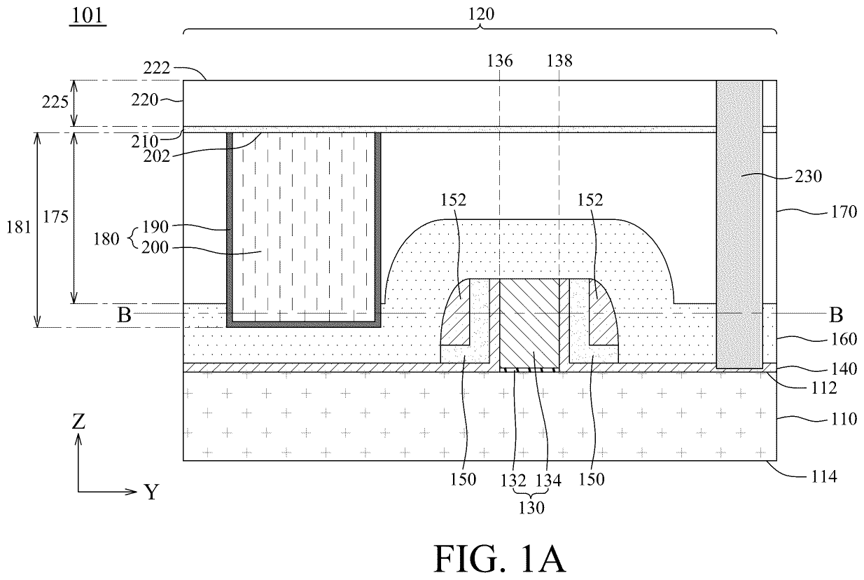

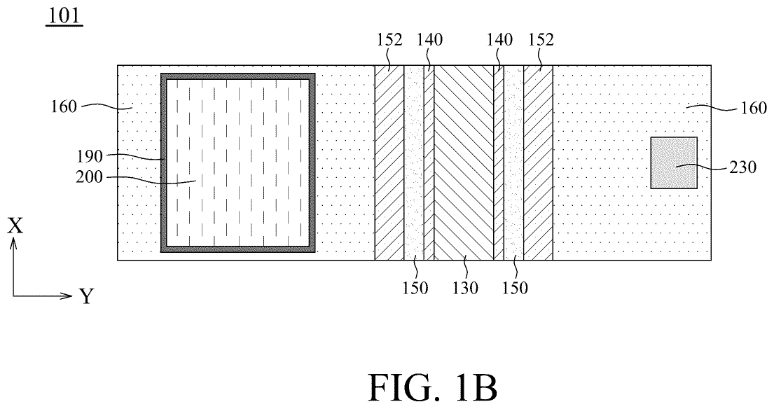

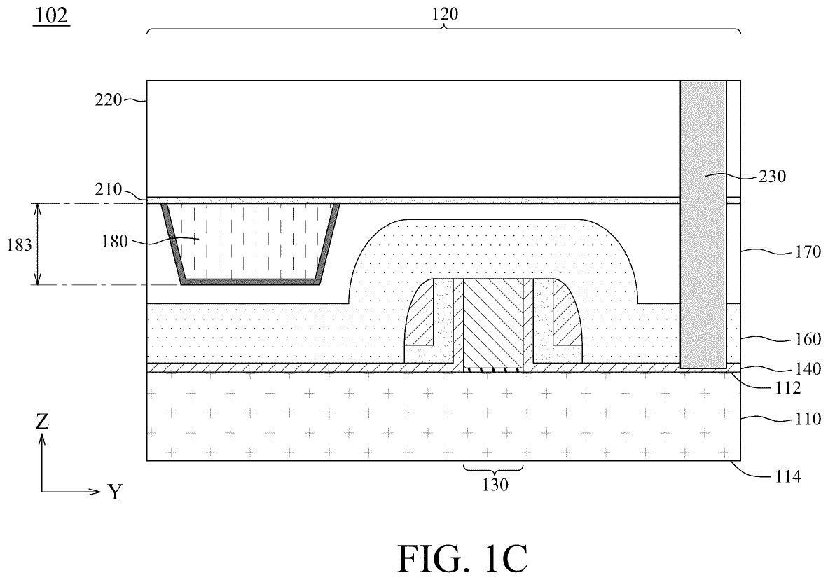

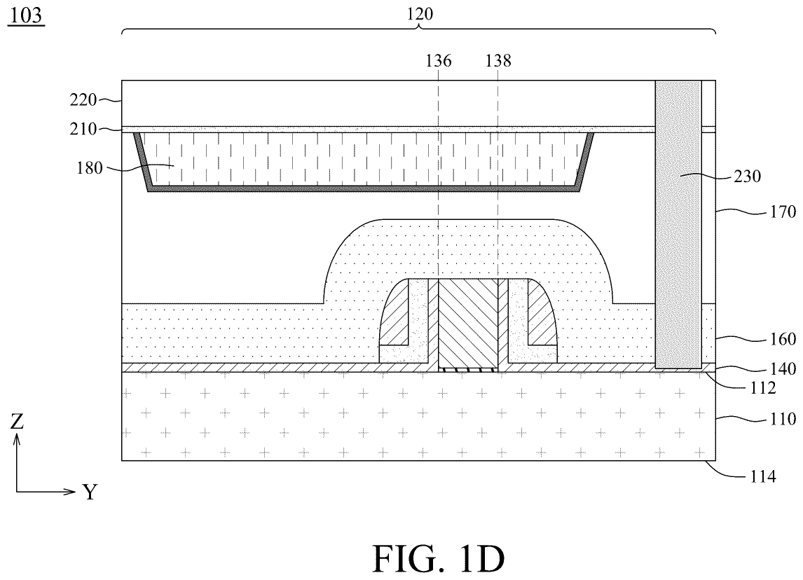

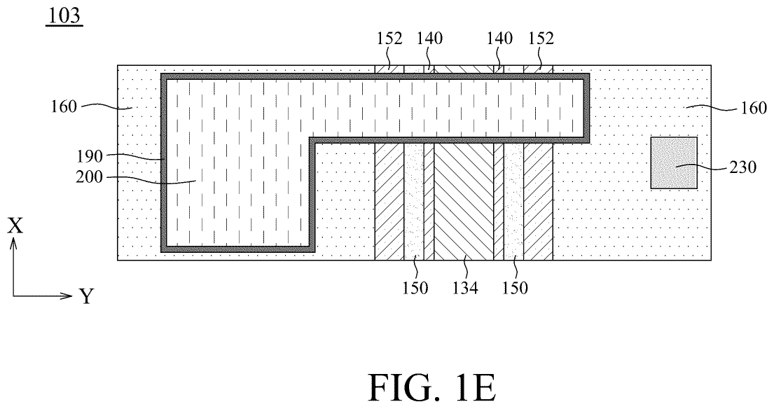

FIG. 1A is a side cross-sectional view showing a first embodiment 101 of the semiconductor device, in accordance with some embodiments of the present disclosure. Here, the light reflector extends into an etch stop layer. FIG. 1B is a plan view of the semiconductor device through line B-B of FIG. 1A.

Referring to both FIG. 1A and FIG. 1B, the semiconductor device 101 is formed upon a substrate 110. The substrate 110 has a first side/front side/upper surface 112 and a second side/back side/lower surface 114. The portion of the substrate illustrated here may be referred to as a pixel unit 120.

A gate structure 130 is present upon the substrate. The gate structure is formed from the combination of a gate dielectric layer 132 upon the substrate and a gate electrode 134 upon the gate dielectric layer 132. A first etch stop layer 140 is present upon the exposed first side of the substrate and the sides of the gate structure 130. One or more interfacial layers 150 are present upon the first etch stop layer 140 and around the gate structure 130. One or more dielectric spacers 152 are located upon the interfacial layers 150. It is noted that two interfacial layers 150 and two dielectric spacers 152 are shown in the cross-sectional view of FIG. 1A, but when considered in three dimensions, they could be joined to each other and could be considered as a single interfacial layer or dielectric spacer, respectively.

Continuing, a second etch stop layer 160 is present upon the substrate. The second etch stop layer covers the gate structure 130, and contacts the first etch stop layer 140 on the other portions of the substrate within the pixel unit. A first dielectric layer 170 is present upon the second etch stop layer 160 and covers the substrate within the pixel unit. The thickness of the first dielectric layer 170 is indicated with reference numeral 175.

The gate structure 130 has a first side 136 and a second side 138 opposite the first side, which are indicated here with dashed lines. A light reflector 180 is located off to a first side 136 of the gate structure 130. It should be noted the light reflector does not contact the gate structure 130. The light reflector 180 is formed from the combination of a high-k adhesive layer 190 and a metal structure 200. As illustrated here, the light reflector 180 extends into the second etch stop layer 160. The high-k adhesive layer 190 is present on all sides of the metal structure except for one side, labeled here as the top side 202 of the metal structure. A barrier layer 210 is present and covers the top side 202 of the metal structure. As illustrated here, the barrier layer 210 extends across the pixel unit. The thickness of the light reflector is measured in the Z-axis, and is indicated here with reference numeral 181.

An interlayer dielectric (ILD) layer 220 is present upon the barrier layer 210. The thickness of the ILD layer 220 is indicated with reference numeral 225. An electrical contact 230 extends from the upper surface 222 of the ILD layer 220 and down into the second etch stop layer 160.

In FIG. 1B, the metal structure 200 is illustrated as a having the three-dimensional shape of a rectangular prism or cuboid, having six sides. The high-k adhesive layer 190 is illustrated as being present on five sides. Generally, one side of the metal structure will not contact the high-k adhesive layer. In addition, in FIG. 1B, the electrical contact 230 may have a relatively small surface area compared to the gate structure 130.

FIG. 1C is a side cross-sectional view of a second embodiment 102 of the semiconductor device. Here, the cross-sectional shape of the light reflector is different. Instead of a rectangular shape as in FIG. 1A, the light reflector 180 is illustrated as having a trapezoidal shape. In addition, the light reflector also has a lower thickness 183 compared to the thickness 181 of the light reflector of FIG. 1A. In addition, the light reflector does not extend into the second etch stop layer 160. More generally, the light reflector may have any shape and the thickness of the light reflector can be varied as desired to obtain the desired performance and/or ease of manufacturing. It is noted that here, the first dielectric layer 170 has a lower thickness and the ILD layer 220 has a greater thickness when compared to FIG. 1A. Generally, their thicknesses may be varied as desired.

FIG. 1D is a side cross-sectional view of a third embodiment 103 of the semiconductor device. Here, the light reflector 180 extends from the first side 136 of the gate structure 130 and over the gate structure. Depending on the desired shape, the light reflector could extend to the second side 138 of the gate structure as well. As seen in the plan view of FIG. 1E, the light reflector may be shaped so that the gate electrode 134 is exposed (in the Z-axis) if desired.

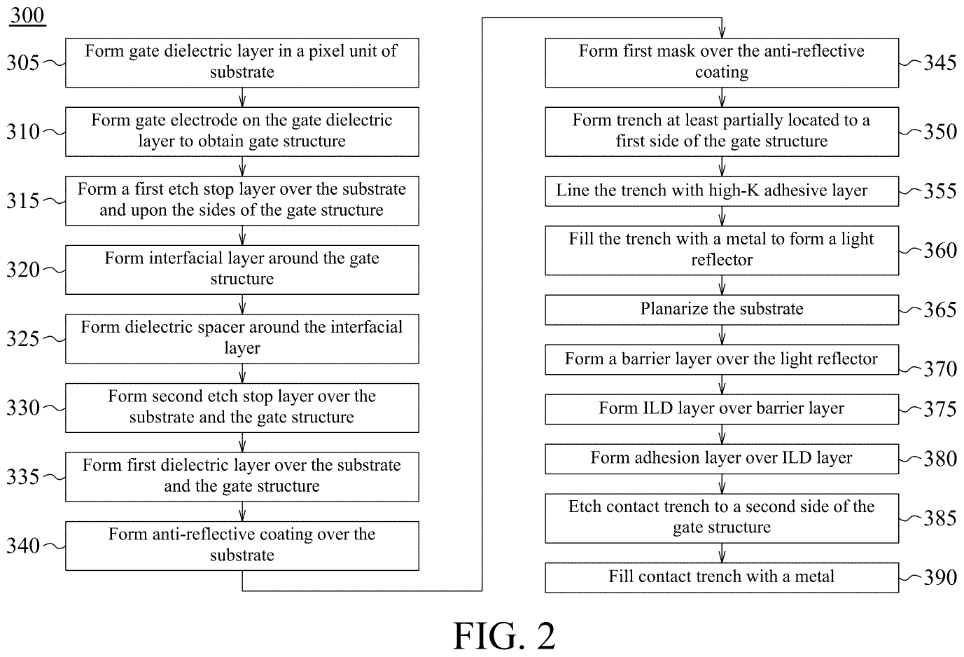

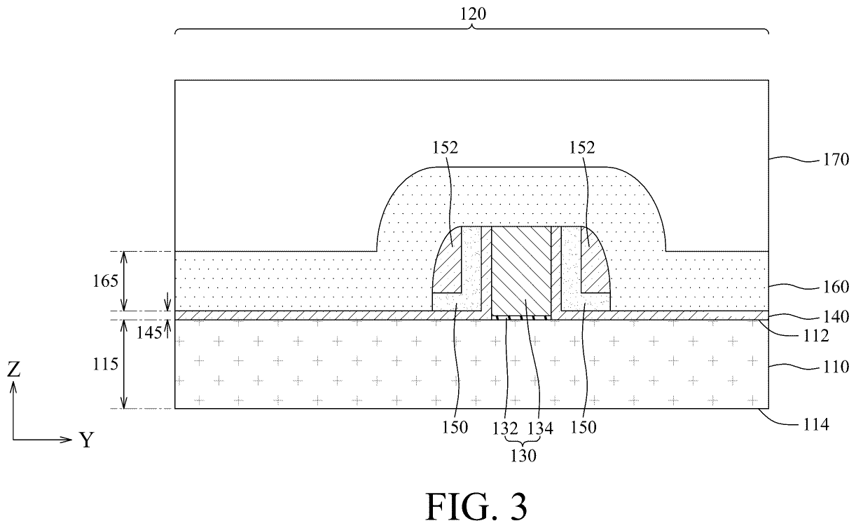

FIG. 2 is a flow chart illustrating a general method 300 for making a semiconductor device, or for making a light reflector upon a substrate, in accordance with some embodiments. Some steps of the method are also illustrated in FIGS. 3-10. These figures provide different views for better understanding. It is noted that in these figures, only Y-axis cross-sectional views are illustrated. While the method steps are discussed below in terms of forming a single light reflector in a single pixel unit, such discussion should also be broadly construed as applying to the formation of multiple light reflectors in multiple pixel units, or the concurrent formation of multiple light reflectors on a substrate. Other structures may also be concurrently formed. It is noted that not all steps described in the flow chart are required, and not all method steps are described in the flow chart.

Referring first to FIG. 3, the method begins with a partially completed integrated circuit or device 101. The device includes a substrate 110, a first etch stop layer 140, gate structure 130, interfacial layer 150, dielectric spacer 152, a second etch stop layer 160, and the first dielectric layer 170. FIG. 3 illustrates a pixel unit 120 of the substrate 110.

The substrate 110 may be, for example, a wafer made of a semiconducting material. Such semiconductor materials can include silicon, for example in the form of crystalline Si. In alternative embodiments, the substrate can be made of other elementary semiconductors such as germanium, silicon carbide (SiC), silicon germanium, or silicon germanium carbide. The substrate may alternatively include a compound semiconductor such as gallium arsenide (GaAs), gallium phosphide, gallium carbide, indium arsenide (InAs), indium phosphide (InP), gallium arsenic phosphide, gallium indium phosphide, cadmium telluride, or cadmium sulfide. In particular embodiments, the substrate is silicon. The substrate 110 has an upper surface 112 and a lower surface 114, and has a thickness 115 between these two surfaces.

In particular embodiments, the first etch stop layer 140 and the second etch stop layer 160 are made of different dielectric materials. For example, the first etch stop layer may be made of silicon dioxide and the second etch stop layer may be made of silicon oxynitride (SiOₓN_{y}). The first etch stop layer 140 has a thickness 145. In particular embodiments, the thickness of the first etch stop layer may range from about 200 angstroms to about 900 angstroms. The second etch stop layer 160 has a thickness 165. In particular embodiments, the thickness of the second etch stop layer is about 400 angstroms or greater. Although there is no theoretical maximum, in some embodiments, the thickness may go up to about 2000 angstroms. Generally, the second etch stop layer 160 is thicker than the first etch stop layer 140. Other ranges and values are also within the scope of this disclosure.

In particular embodiments, the first etch stop layer 140 and the interfacial layer 150 are made of different dielectric materials. Similarly, the interfacial layer 150 and the dielectric spacer 152 may be made of different dielectric materials. The gate electrode 134 of the gate structure may be made of any appropriate electrically conductive material or metal, for example polysilicon. The various layers may be made or formed using any appropriate method, for example, chemical vapor deposition (CVD), physical vapor deposition (PVD), or atomic layer deposition (ALD).

Referring to both FIG. 2 and FIG. 3 concurrently, the pixel unit 120 may be prepared by first, as indicated in step 305 of FIG. 2, forming a gate dielectric layer 132. This may be done by deposition and appropriate patterning. Then, in step 310, the gate electrode 134 is formed upon the gate dielectric layer 132 to obtain the gate structure 130. Next, in step 315, the first etch stop layer 140 is formed. The first etch stop layer covers the exposed portions of the substrate within the pixel unit 120 and also covers the sides of the gate structure 130. Continuing, in step 320, the interfacial layer 150 is applied around the gate structure. As illustrated here, the interfacial layer has an L-shaped cross-section. Then, in step 325, one or more dielectric spacers 152 are formed around the interfacial layer. Next, in step 330, the second etch stop layer 160 is formed. The second etch stop layer directly contacts the first etch stop layer 140 on either side of the gate structure 130. The second etch stop layer 160 also covers the gate structure 130. Finally, in step 335, the first dielectric layer 170 is deposited over the substrate within the pixel unit 120, including over the gate structure 130. In some particular embodiments, the first dielectric layer is formed from tetraethyl orthosilicate (TEOS) or borophosphorous tetraethyl orthosilicate (BPTEOS), although other materials may be used if desired.

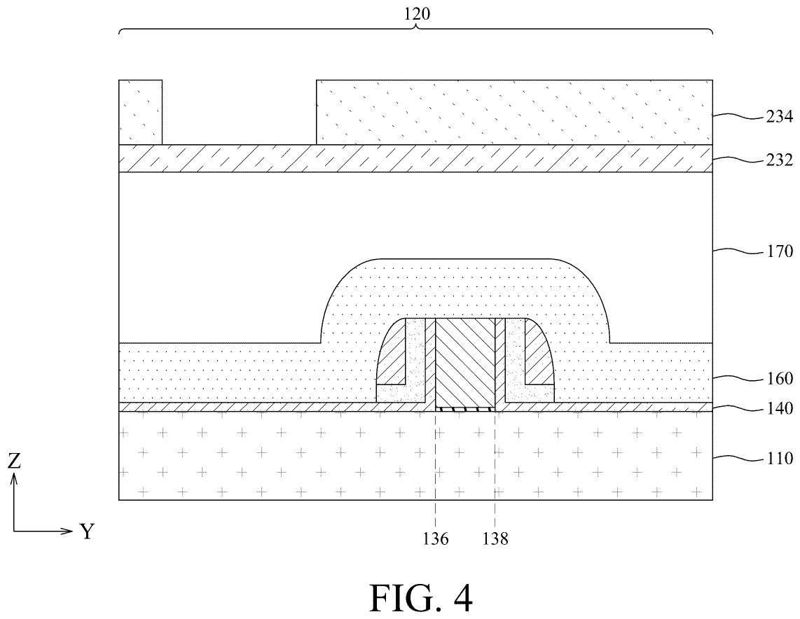

Next, in step 340 of FIG. 2 and as illustrated in FIG. 4, an anti-reflective coating 232 is formed over the pixel unit 120. Then, in step 345 of FIG. 2, a first mask 234 is formed over the anti-reflective coating 232 and patterned. The portion of the pixel unit off to the first side 136 of the gate structure is exposed. In particular embodiments, extreme ultraviolet (EUV) light having a wavelength of about 13.5 nm is used for patterning, as this permits smaller feature sizes to be obtained.

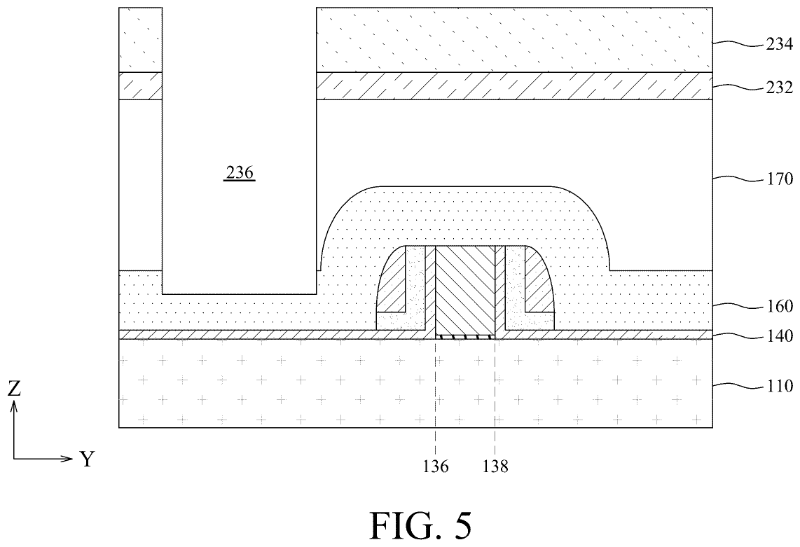

Next, in step 350 of FIG. 2 and as illustrated in FIG. 5, etching is performed to form a trench 236. The trench 236 is located to at least the first side 136 of the gate structure 130. As illustrated here, the trench 236 extends into the second etch stop layer 160. However, as illustrated in FIGS. 1A-1E, this is not required. The trench should not extend to the substrate. The first mask is then removed.

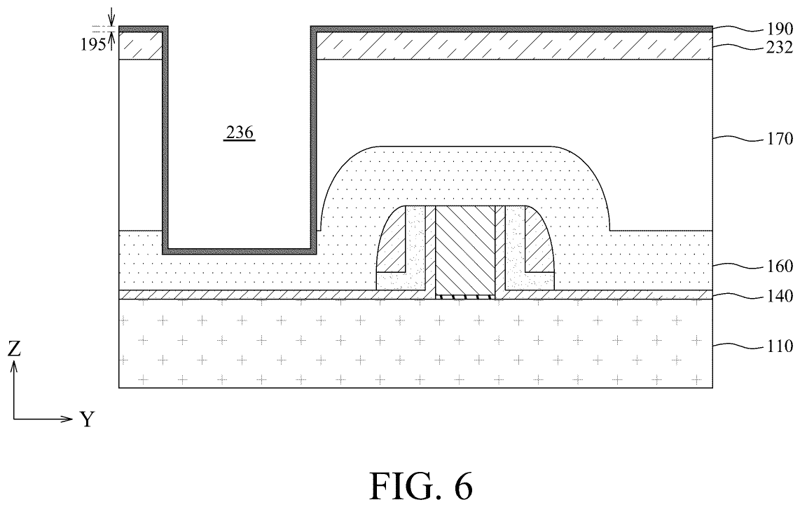

Then, in step 355 of FIG. 2 and as illustrated in FIG. 6, the trench 236 is lined with a high-k adhesive layer 190. The adhesive layer may also be considered a glue layer. The term “high-k” refers to the material having a dielectric constant that is greater than that of silicon dioxide (k=3.9). In some embodiments, the high-k material has a dielectric constant of 4 or greater, including 5 or greater, or 9 or greater. Some non-limiting examples of suitable materials for the high-k adhesive layer include aluminum oxide (Al₂O₃), titanium nitride (TiN), and tantalum nitride (TaN). In particular embodiments, the thickness 195 of the high-k adhesive layer may range from about 90 angstroms to about 110 angstroms. Other ranges and values are also within the scope of this disclosure. The high-k adhesive layer may be formed by CVD, PVD, or ALD, or other suitable process.

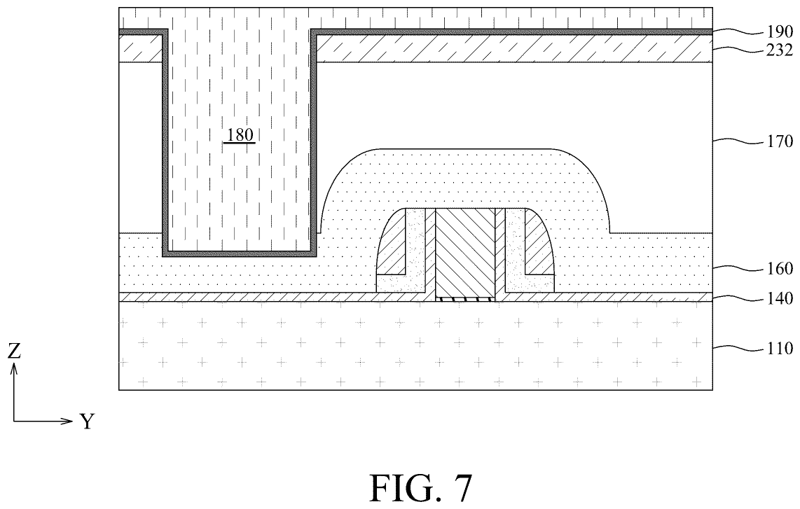

Subsquently, in step 360 of FIG. 2 and as illustrated in FIG. 7, the trench 236 is filled with a metal. This forms a light reflector 180. Desirably, the metal is a zero metal, i.e. has no net charge. Some non-limiting examples of suitable metals may include elemental metals such as copper (Cu) or tungsten (W), or metal alloys such as AlCu. In particular embodiments, copper is used. The metal may be deposited, for example, by evaporation or sputtering, or other suitable methods.

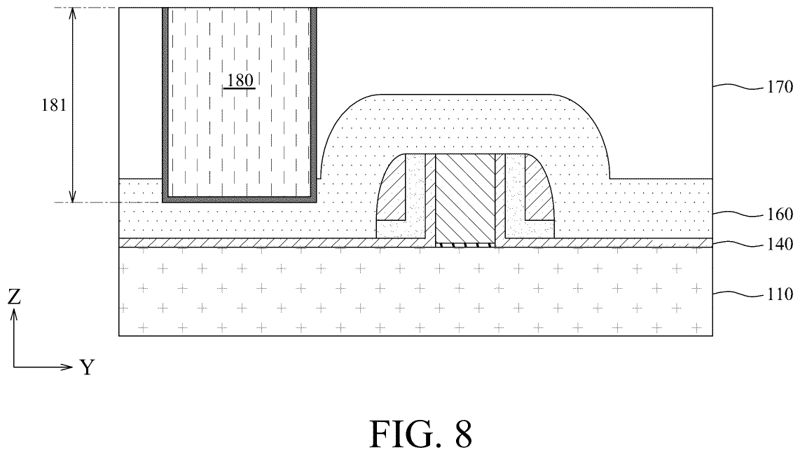

Next, in step 365 of FIG. 2 and as illustrated in FIG. 8, the substrate is planarized to obtain a flat surface. As illustrated here, the anti-reflective coating 232 is removed, along with the portions of the high-k adhesive layer and excess metal which were present upon the anti-reflective coating. The planarizing may be performed, for example, using a chemical mechanical polishing (CMP) process. Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate and/or the top layer thereon, removing undesired materials and creating a highly level surface. A post-CMP cleaning step is then carried out using rotating scrubber brushes along with a washing fluid to clean one or both sides of the wafer substrate.

The thickness 181 of the light reflector 180 may range from greater than zero to about 4000 angstroms, including about 10 angstroms to about 4000 angstroms, or about 100 angstroms to about 2000 angstroms, or about 1000 angstroms to about 4000 angstroms. Other ranges and values are also within the scope of this disclosure.

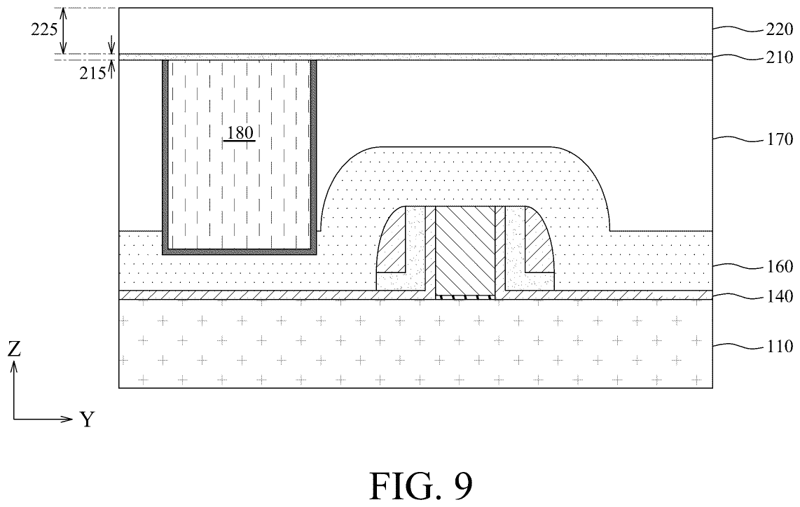

Then, in step 370 of FIG. 2 and as illustrated in FIG. 9, a barrier layer 210 is formed over the light reflector 180. The barrier layer may also be formed over the rest of the pixel unit. The barrier layer seals the light reflector and desirably reduces or prevents migration of the metal. Some non-limiting examples of suitable materials for the barrier layer include silicon nitride (SiN), silicon oxynitride (SiOₓN_{y}), and aluminum oxide (Al₂O₃), and generally any other high-k dielectric material. In particular embodiments, the thickness 215 of the barrier layer may range from about 100 angstroms to about 1000 angstroms. Other ranges and values are also within the scope of this disclosure.

Then, in step 375 of FIG. 2, the interlayer dielectric (ILD) layer 220 is formed over the barrier layer 210. The ILD layer may be any suitable dielectric material. In particular embodiments, the thickness 225 of the ILD layer may range from about 100 angstroms to about 2000 angstroms. Other ranges and values are also within the scope of this disclosure.

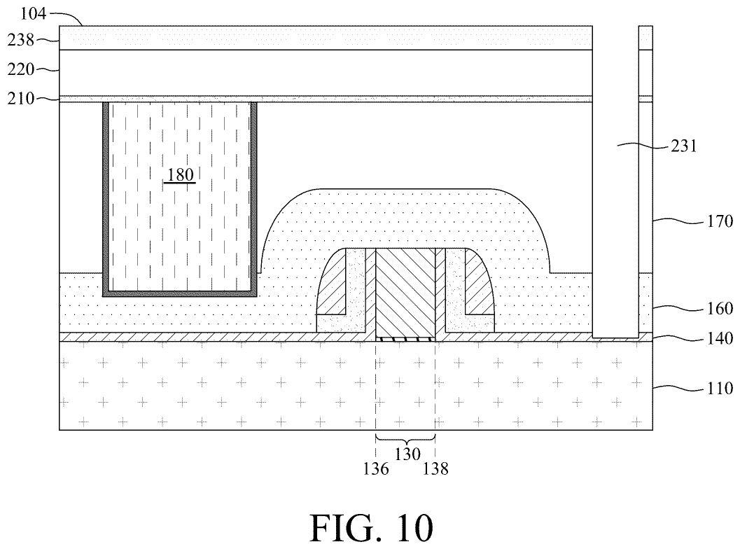

Continuing, in optional step 380 of FIG. 2 and as illustrated in FIG. 10, an adhesion layer 238 can be formed over the substrate and within the pixel unit. Then in step 385 of FIG. 2, etching is performed to form a contact trench 231 off to the second side 138 of the gate structure 130. As illustrated here, the contact trench 231 extends from the upper surface 104 of the device down through the second etch stop layer 160 and into the first etch stop layer 140. The contact trench does not contact the gate structure 130 or the substrate 110.

Then, in step 390 of FIG. 2, the contact trench is filled with a metal to form an electrical contact 230. Non-limiting examples of metals can include tungsten (W) and copper (Cu). The resulting semiconductor device is shown in FIG. 1A.

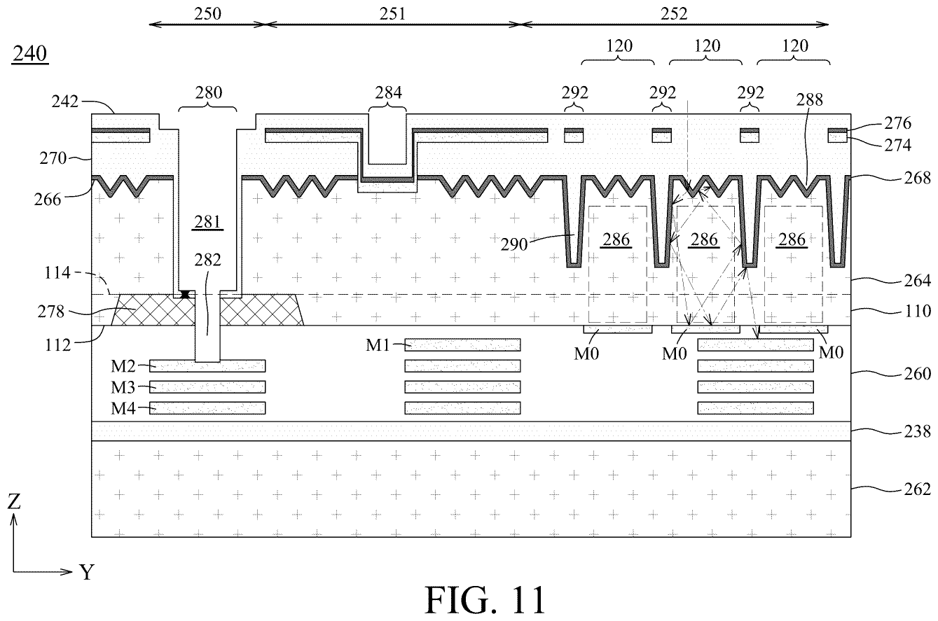

The semiconductor device of FIGS. 1A-1E may be used in an image sensor, such as an active-pixel sensor (CMOS sensor or CIS). The image sensor may be a Back-Side-Illuminated (BSI) or Front-Side-Illuminated (FSI) image sensor. FIG. 11 is a schematic diagram illustrating a BSI image sensor 240, in accordance with some embodiments of the present disclosure. In this figure, a greater portion of the substrate 110 is shown compared to FIGS. 1A-1E.

Initially, the semiconductor device of FIGS. 1A-1E containing a light reflector is indicated in FIG. 11 as forming the M0 layer. The substrate 110 is shown with the second side 114 of the substrate facing upwards towards the top of the figure.

An interconnect layer 260 is illustrated on the first side 112 of the substrate. The interconnect layer permits various components to communicate with each other, and may also be considered a redistribution layer (RDL). The interconnect layer can be formed from one or more combinations of thinner dielectric layers (not shown) and etch stop layers (not shown). Each individual dielectric layer can independently be considered an intermetal dielectric (IMD) layer or an interlayer dielectric (ILD) layer. The dielectric layers include electrically conductive features which are used for communication between various components on the substrate. An interconnect layer may have several dielectric layers, with the conductive features being vertically interconnected by vias. As illustrated here, the interconnect layer 260 includes four IMD layers labeled as M1, M2, M3, and M4 which include metal routing. An optional adhesion layer 238 is illustrated contacting the interconnect layer 260 to a carrier wafer 262.

The substrate 110 is divided into three different regions, including a scribe line region 250 on the left-hand side, a metal ground region 251, and a pixel region 252 on the right-hand side. Continuing, a silicon layer 264 is present upon the second side 114 of the substrate 110 (separated by dashed line). The silicon layer may alternatively be considered part of the substrate 110 as well. The upper surface 266 of the silicon layer includes a plurality of light focusing structures 288 (shown here with triangular cross-section). A high-k dielectric film 268 covers the upper surface 266 of the silicon layer. A second dielectric layer 270 covers the high-k dielectric film. Also located within the second dielectric layer 270 is a set of dielectric layers 274, 276 that act as light guiding structures, and at least one of which is opaque and non-transmissive to NIR wavelengths.

An STI pad 278 is presented in the scribe line region 250 next to the interconnect layer 260. An empty trench 280 extends from the upper surface 242 of the sensor 240 down through the STI pad and into the interconnect layer 260, here shown as contacting the M2 layer.

In the metal ground region 251, a ground trench 284 is present in the upper surface. The metal ground region is also covered by the dielectric layers 274, 276, and so the substrate in this region is not exposed to NIR light.

Referring now to the pixel region 252, the pixel region contains one or more pixel units 120. Three such pixel units are illustrated here. Each pixel unit includes a photodiode 286 located above the light reflector in the M0 layer. The gate structure in the M0 layer and the photodiode will together act as a transfer transistor. Light focusing structures 288 are present above each pixel unit. In three dimensions, these light focusing structures have a pyramidal shape. The pixel units are isolated from each other by deep trench isolation (DTI) regions 290. It is noted the light focusing structures are not as deep as the DTI regions. Light guiding structures 292 are present in the second dielectric layer 270 above the DTI regions 290, to guide light towards the photodiodes 286.

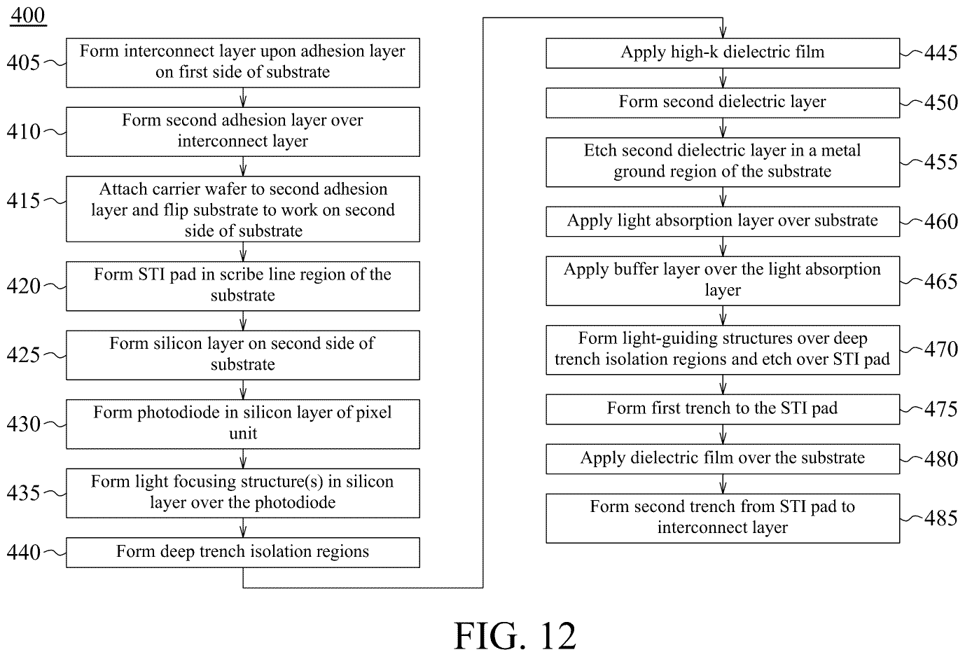

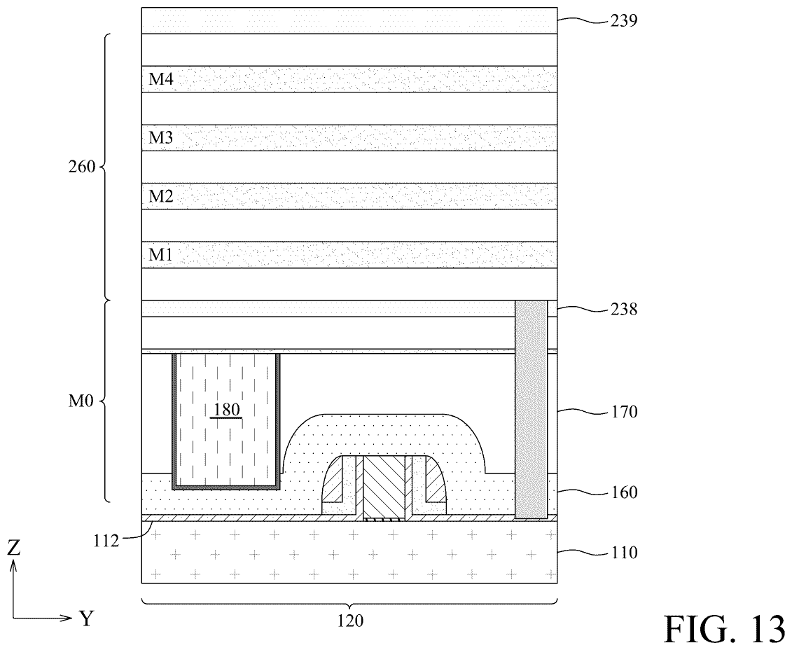

FIG. 12 is a flow chart illustrating a general method 400 for making a semiconductor device, such as an image sensor, in accordance with some embodiments. Some steps of the method are also illustrated in FIGS. 13-21. These figures provide different views for better understanding. It is noted that in these figures, only Y-axis cross-sectional views are illustrated. While the method steps are discussed below in terms of forming a single device, such discussion should also be broadly construed as applying to the concurrent formation of multiple devices. Other structures may also be concurrently formed. It is noted that not all steps described in the flow chart are required, and not all method steps are described in the flow chart.

Initially, the method begins with the structure of FIG. 1A. Then, in step 405 of FIG. 12 and as illustrated in FIG. 13, an interconnect layer 260 is formed upon the first side 112 of the substrate 110. Here, the structure of FIG. 1A is labeled as the M0 layer. The interconnect layer 260 is illustrated as a dielectric layer containing four IMD layers labeled as M1, M2, M3, and M4. In step 410 of FIG. 12, a second adhesion layer 239 is formed upon the interconnect layer 260.

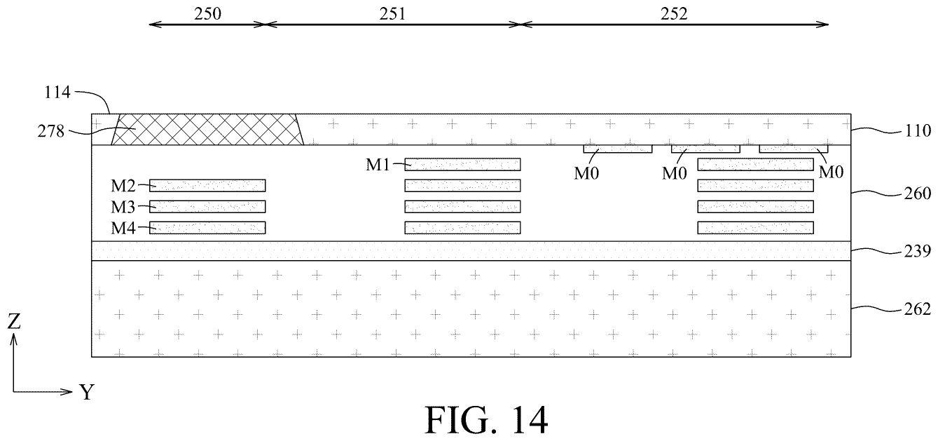

Then, in step 415 of FIG. 12, a carrier wafer 262 is attached to the second adhesion layer 239 and the substrate is flipped so that the second side 114 of the substrate faces upward, to permit processing steps to be performed upon the second side of the substrate. This is illustrated in FIG. 14. Again, while FIG. 13 illustrates one pixel unit 120, FIG. 14 shows a larger portion of the substrate 110, or could be described as providing a view that is zoomed out relative to FIG. 13.

Continuing, in step 420 of FIG. 12 and as illustrated in FIG. 14, a short trench isolation (STI) pad 278 is formed in the scribe line region 250 of the substrate 110. The STI pad can be formed by patterning the substrate, etching a trench, and filling the trench with a dielectric material. The dielectric material in the STI pad is commonly silicon dioxide, although other dielectric materials can also be used such as undoped polysilicon, silicon nitride, silicon oxynitride, fluoride-doped silicate glass, or another high-k or low-k dielectric material. The deposition can be done using CVD, PVD, or spin-on processes known in the art. If desired, the dielectric material can be deposited to a level above that of the substrate surface 114, then recessed back down to the desired height.

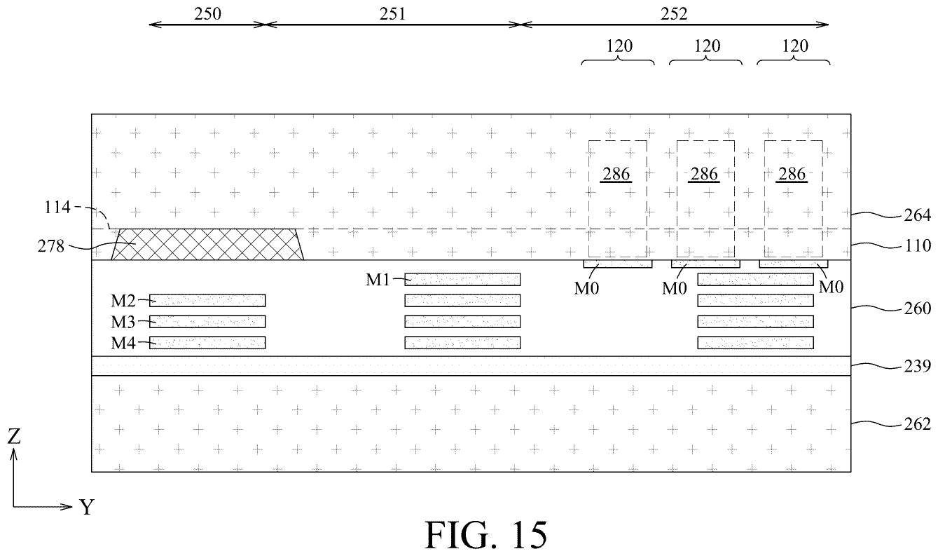

Then, in step 425 of FIG. 12 and as illustrated in FIG. 15, a silicon layer 264 is formed on the second side 114 of the substrate. In particular embodiments where the substrate is made of silicon, this processing step may also be described as thickening the substrate. This may be done, for example, by molecular beam epitaxy (MBE), PVD, CVD, or other suitable methods. The crystalline orientation of the silicon layer will match that of the substrate 110.

Next, in step 430 of FIG. 12, and as illustrated in FIG. 15, a photodiode 286 is formed in the silicon layer of each pixel unit 120. The photodiode may also be described interchangeably as being on or within the substrate. A photodiode can be formed, for example, as a P-N junction diode from the combination of a deep doped region and a shallow doped region. The deep doped region is formed by doping with a first dopant type. The shallow doped region is formed by doping with a second dopant type. The first dopant type and the second dopant type are of opposite charge. For example, if the first dopant type is an n-type dopant, then the second dopant type is a p-type dopant, and vice versa. Common p-type dopants may include boron, gallium, or indium. Common n-type dopants may include phosphorus or arsenic. The photodiode may alternatively be a PIN photodiode or an avalanche photodiode. In operation, the photodiode may be biased or unbiased.

The doping may be performed by ion implantation, which modifies the conductivity of the silicon crystal lattice in the implanted location. An ion implanter generally includes an ion source, a beam line, and a process chamber. The ion source produces desired ions which act as dopants to change various properties in desired locations of the base layer. The resulting ion beam enters the beam line, which organizes the ions into a beam having high purity in terms of ion mass, energy, and species. The ion beam is then used to irradiate the substrate in the process chamber. The dosage, energy, implant angle, and other parameters may be used to control the depth at which the dopant is implanted in the substrate.

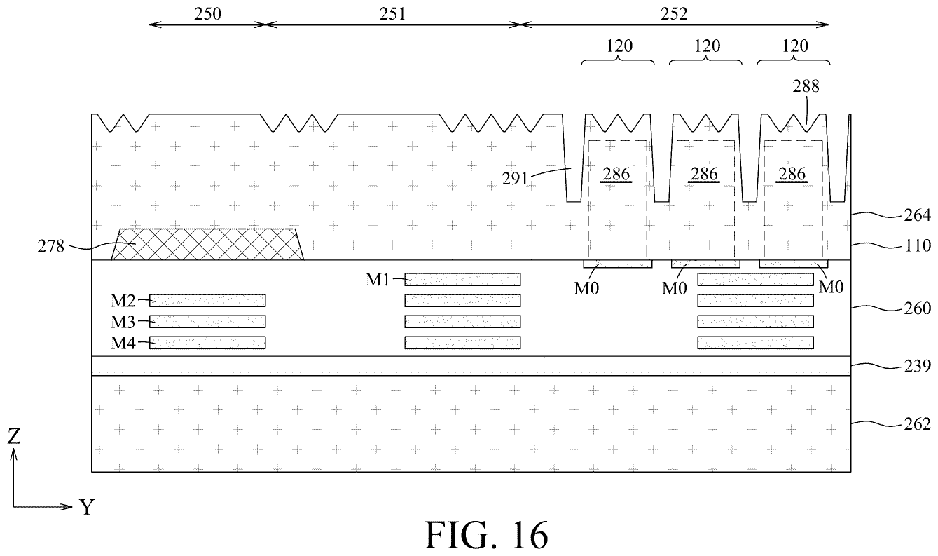

Subsequently, in step 435 of FIG. 12 and as illustrated in FIG. 16, one or more light focusing structures 288 are formed in the silicon layer above each pixel unit. These structures focus light from a relatively large surface area into a relatively smaller surface area for the purpose of improving light absorption by the photodiode. These structures may be formed by appropriate patterning of a mask and subsequent etching, for example by wet etching.

Then, in step 440 of FIG. 12 and as illustrated in FIG. 16, deep trench isolation (DTI) trenches 291 are formed to isolate adjacent pixel units 120 and their photodiodes 286 from each other. The DTI trenches extend further into the silicon layer 264 than the light focusing structures. These structures may be also be formed by appropriate patterning of a mask and subsequent etching.

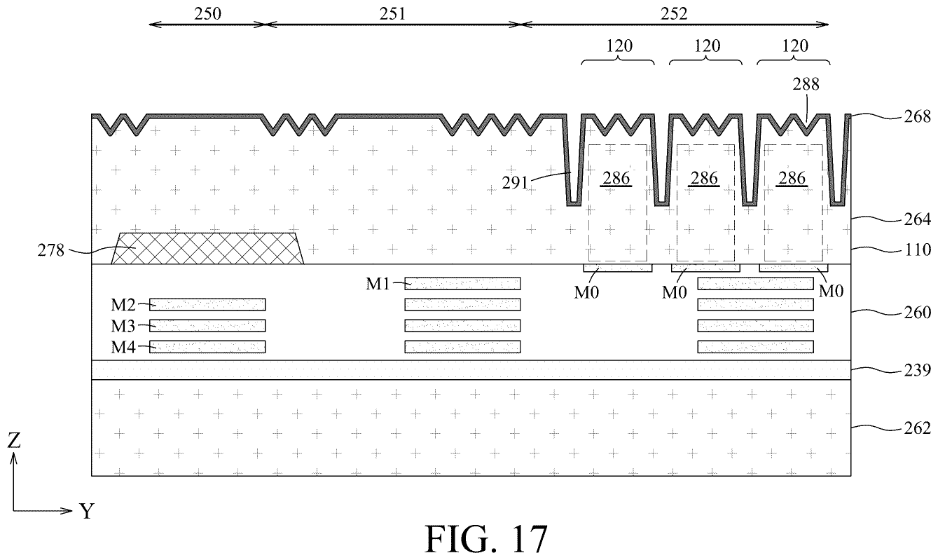

Continuing, in step 445 of FIG. 12 and as illustrated in FIG. 17, a high-k dielectric film 268 is applied over the second side 114 of the substrate. As illustrated here, the high-k dielectric film is present in the scribe line region 250, the metal ground region 251, and the pixel region 252, and lines the light focusing structures 288 and the DTI trenches 291. However, the high-k dielectric film does not completely fill the light focusing structures 288 or the DTI trenches 291. The high-k dielectric film may be formed by CVD, PVD, or ALD, or other suitable process.

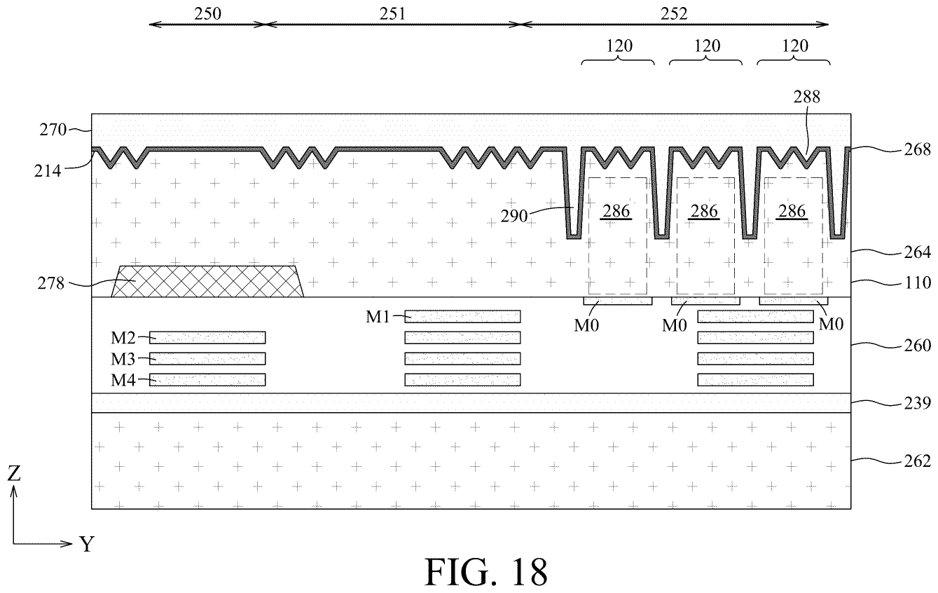

Then, in step 450 of FIG. 12 and as illustrated in FIG. 18, a second dielectric layer 270 is applied over the second side 214 of the substrate. The second dielectric layer covers the scribe line region 250, the metal ground region 251, and the pixel region 252, and fills the light focusing structures 288 and the DTI trenches. The second dielectric layer is formed from an optically transparent material that transmits light, especially NIR wavelengths. In particular embodiments, the second dielectric layer is formed from silicon dioxide (SiO₂), although any suitable material can be used. The second dielectric layer can be formed by any suitable process. Planarization may be performed to obtain a flat surface, if desired.

The filling of the DTI trenches forms deep trench isolation (DTI) regions 290 that electrically isolate adjacent pixel units 120 and their photodiodes 286 from each other. This reduces cross-talk between the pixel units.

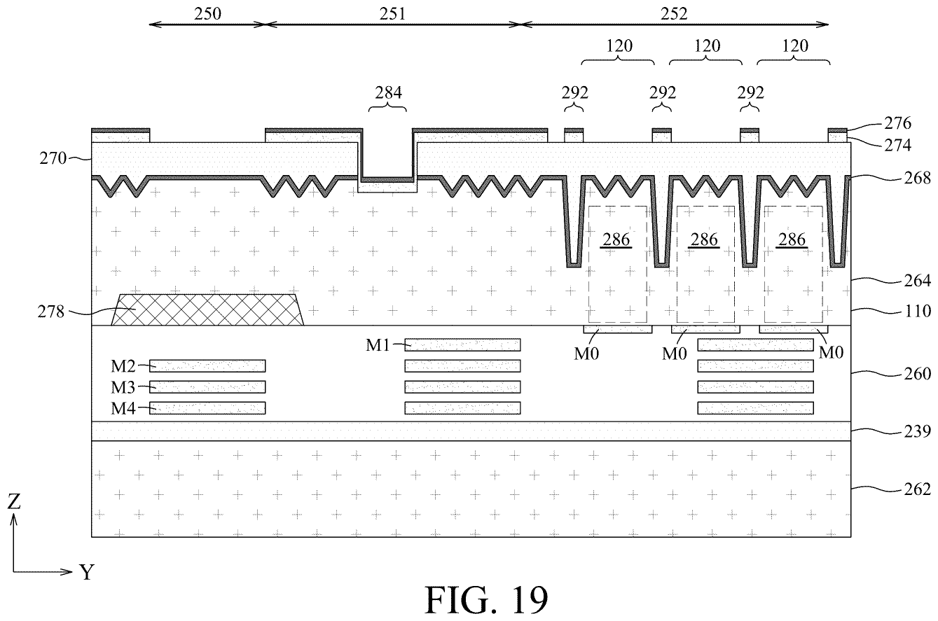

Next, in step 455 of FIG. 12 and as illustrated in FIG. 19, the second dielectric layer is etched to form a ground trench 284 in the metal ground region 251 of the substrate. Then, in step 460 of FIG. 12, a light absorption layer 274 is applied over the substrate. This layer is formed from a material that absorbs light, especially NIR wavelengths. Some non-limiting examples of suitable materials for the light absorption layer may include aluminum-copper (AlCu) and titanium nitride (TiN). This layer may be formed by CVD, PVD, or ALD, sputtering, or other suitable process.

Next, in step 465 of FIG. 12, a buffer layer 276 is applied over the light absorption layer 274. The buffer layer may be used to control the refractive index, to reduce dark current, and/or improve electrical isolation. The buffer layer is usually a dielectric material, and desirably is transparent to light, especially NIR wavelengths. In some particular embodiments, the buffer layer is formed from silicon oxynitride (SiOₓN_{y}). This layer may be formed by any suitable process. It is noted the two layers 274/276 are applied as films (i.e. with a constant thickness), in contrast to the second dielectric layer 270.

Continuing, in step 470 of FIG. 12, the light absorption layer 274 and the buffer layer 276 are then patterned and etched. In the pixel region 252, light guiding structures 292 are formed from the combination of the light absorption layer 274 and the buffer layer 276 over the DTI regions. The light absorption layer 274 and the buffer layer 276 are removed from the area over each photodiode 286, so that the second dielectric layer 270 is exposed. The light guiding structures 292 direct light away from the DTI regions and towards the photodiodes 186. In the scribe line region 250, the light absorption layer 274 and the buffer layer 276 are removed from an area over the STI pad.

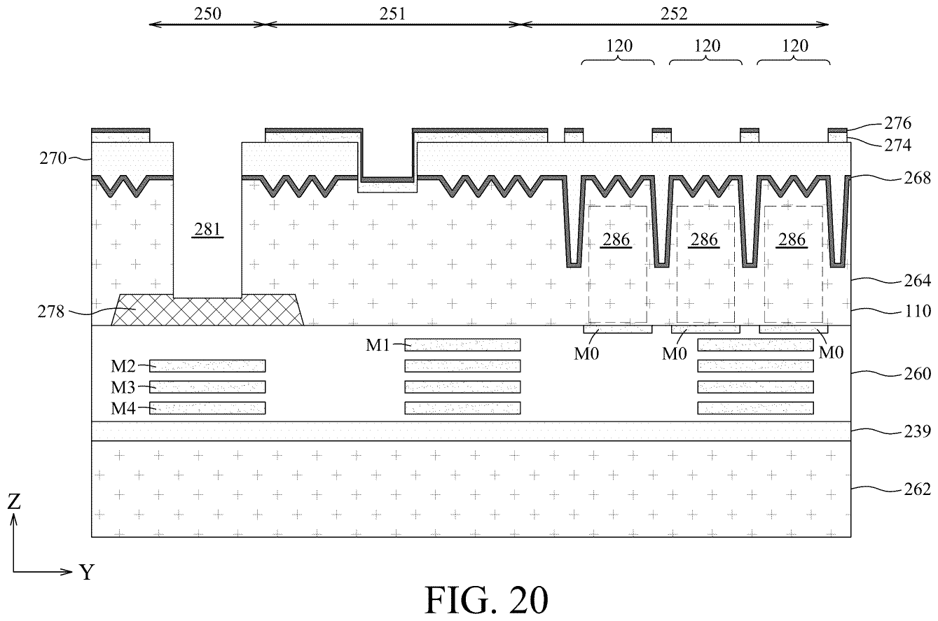

Subsequently, in step 475 of FIG. 12 and as illustrated in FIG. 20, a first trench 281 is formed in the scribe line region 250. The first trench extends downwards from the upper surface 242 through the second dielectric layer 270 and the silicon layer 264/substrate 110 to the STI pad 278. This may be performed by dry etching.

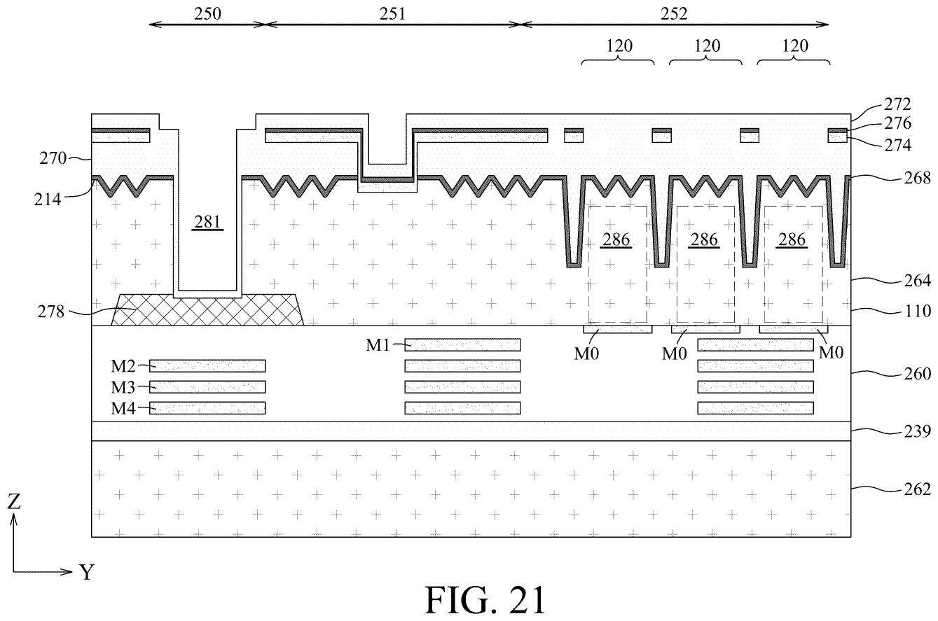

Next, in step 480 of FIG. 12 and as illustrated in FIG. 21, a dielectric film 272 is a pplied over the second side 114 of the substrate. In particular embodiments, the dielectric film is the same material as used for the second dielectric layer 270. The dielectric layer covers the light absorption layer 274 and the buffer layer 276 across the scribe line region, the metal ground region 251, and the pixel region 252. The dielectric film 272 also covers the exposed surfaces of the first trench 281.

Finally, in step 485 of FIG. 12 and referring back to FIG. 11, a second trench 282 is formed in the scribe line region 250. The second trench is etched from the bottom of the first trench 281 down to the interconnect layer 260. As illustrated here, the second trench terminates at the M2 layer, where it connects with metal routing. The resulting trench 280 in the scribe line region will be used for device testing, such as Wafer Acceptance Testing (WAT). The final structure is shown in FIG. 11.

Other structures, such as a color filter and microlens, may be formed on the image sensor as desired in appropriate locations to obtain a BSI or FSI image sensor. The color filter can filter the light by wavelength range and provide information about the light intensity. The microlens may be of a size and shape that is suitable for increasing the light collection efficiency of the image sensor by concentrating incident light on the sensor to the active area (i.e., photodiode), which covers only a part of the surface area of the entire image sensor.

The structures and methods of the present disclosure discussed above refer to dielectric layers. Such dielectric layers can generally be made from any suitable dielectric material or combination thereof, although the characteristics of any particular layer may also be further defined. Examples of dielectric materials may include silicon dioxide (SiO₂), silicon nitride (Si₃N₄), silicon carbide (SiC), hafnium dioxide (HfO₂), zirconium dioxide (ZrO₂), aluminum oxide (Al₂O₃), silicon oxynitride (SiOₓN_{y}), hafnium oxynitride (HfOₓN_{y}) or zirconium oxynitride (ZrOₓN_{y}), or hafnium silicates (HfSiₓO_{y}) or zirconium silicates (ZrSiₓO_{y}) or silicon carboxynitride (SiCₓO_{y}N_{z}), or hexagonal boron nitride (hBN). Other dielectric materials may include tantalum oxide (Ta₂O₅), nitrides such as silicon nitride, polysilicon, phosphosilicate glass (PSG), fluorosilicate glass (FSG), undoped silicate glass (USG), high-stress undoped silicate glass (HSUSG), and borosilicate glass (BSG). The dielectric layer may be formed by any suitable means, including chemical vapor deposition (CVD), physical vapor deposition (PVD), atomic layer deposition (ALD), thermal oxidation, or other suitable methods.

It is also noted that certain conventional steps are not expressly described in the discussion above. For example, a pattern/structure may be formed in a given layer by applying a photoresist layer, patterning the photoresist layer, developing the photoresist layer to form a mask, and then etching through the mask to transfer the pattern to the given layer.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the photoresist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern (i.e. a mask). One example of a common developer is aqueous tetramethylammonium hydroxide (TMAH). Generally, any suitable developer may be used. Sometimes, a post develop bake or “hard bake” may be performed to stabilize the photoresist pattern after development, for optimum performance in subsequent steps.

Continuing, portions of the given layer below the patterned photoresist mask are now exposed. Etching transfers the photoresist pattern to the given layer below the patterned photoresist mask. After use, the mask can be removed, for example, using various solvents such as N-methyl-pyrrolidone (NMP) or alkaline media or other strippers at elevated temperatures, or by dry etching using oxygen plasma.

Generally, any etching step described herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Finally, cleaning steps such as wet cleaning may be performed between various processing steps. The cleaning solution will depend on the etch recipe and the exposed layers. Examples of cleaning solutions may include deionized water, dilute HF, and other conventional solutions.

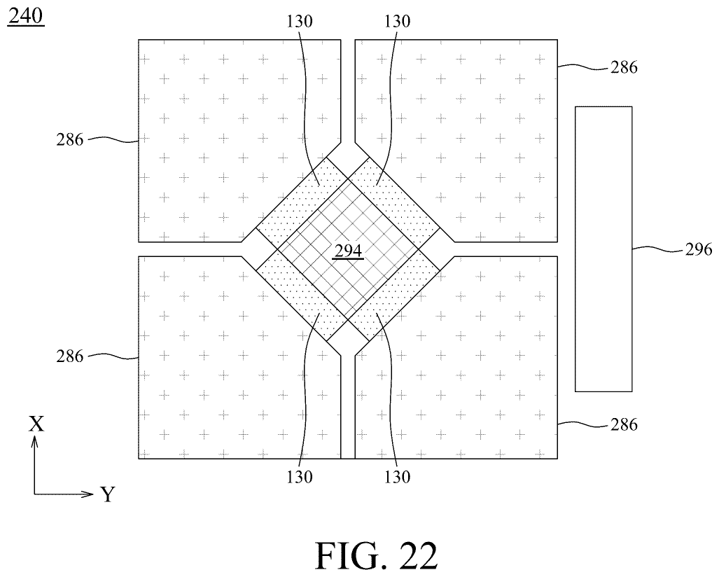

FIG. 22 is a plan view of another embodiment of an image sensor 240. In this embodiment, four photodiodes 286 are illustrated along with four gate structures 130. Each individual photodiode is electrically connected by an individual gate structure to the same floating node 294. The photodiodes are electrically isolated from each other, and together surround the floating node. This configuration may also be electrically connected to other devices like capacitors or various transistors, such as a source follower transistor, a reset transistor, a row select transistor, or the like, which can be located in a device region 296 adjacent the photodiodes. The source follower transistor permits the charge on the floating node to be observed without removing the charge. The reset transistor clears the charge stored at the floating node when activated. The row select transistor permits selection of the image sensor when arranged in a row with other image sensors.

The structure of this image sensor may be useful, for example, with a Bayer filter that uses two green-sensitive photodiodes, one red-sensitive photodiode, and one blue-sensitive photodiode.

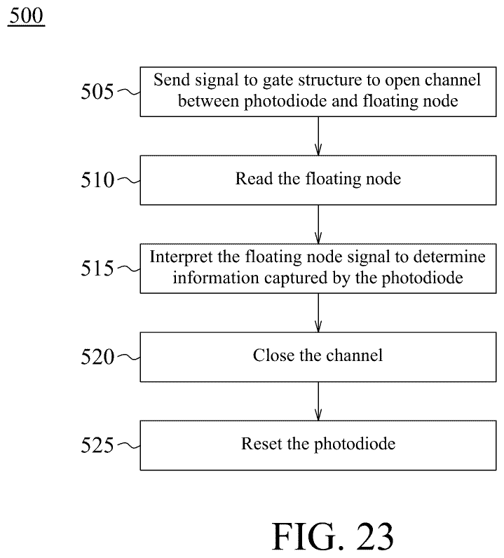

FIG. 23 is a flow chart illustrating a method 500 for using an image sensor, in accordance with some embodiments. The method steps are discussed below in terms of using a single image sensor, and should also be broadly construed as applying to the concurrent use of multiple image sensors. Reference is also made to the structure of FIG. 11.

Initially, the photodiode stores an electrical charge. In step 505 of FIG. 22, a signal is sent to a gate structure 150. Typically, a voltage signal is sent, either in the form of an increased voltage or a decreased voltage (depending on how the gate structure is operated). This opens a channel between the photodiode 120 and the floating node 130, which permits current to flow from the photodiode 120 to the floating node 130. In step 510, the floating node is then read, and in step 515 the signal from the floating node is interpreted by an image processing chip to determine parameters captured by the photodiode. Non-limiting examples of such parameters may include the color (wavelength) and brightness. When the voltage signal ceases, the channel is closed, as indicated in step 520. In step 525, the photodiode is reset (using the reset transistor).

The image sensors of the present disclosure may be incorporated into larger semiconductor packages. Such packages may also include various interconnect structures. Various applications for the image sensors may include image signal processors (ISP); LCD, OLED, AMOLED, or QLED display panels; image sensors that can be used in systems such as cameras, mobile telephones, computers or tablets or other electronic devices, facial recognition systems, or as motion sensors for automotive applications, security applications, energy efficiency, etc.

The structures of the present disclosure have several advantages. The light reflector below the photodiode redirects light to the photodiode that would otherwise not be captured. The quantum efficiency of the image sensor is enhanced, especially for NIR wavelengths. The size and shape of the light reflector can be changed and controlled as desired as well.

Some embodiments of the present disclosure thus relate to methods for making a semiconductor device. A trench is formed which is at least partially located to a first side of a gate structure. The trench is lined with a high-k adhesive layer, and then filled with a metal to form a light reflector.

Other embodiments disclosed herein relate to semiconductor devices. The devices comprise a gate structure upon a substrate. A first dielectric layer is present over the substrate. A light reflector is located in the first dielectric layer off to one side of the gate structure. The light reflector comprises a metal structure and a high-k adhesive layer.

Also described in various embodiments herein are image sensors that comprise a substrate. A gate structure is present on a first side of the substrate. A light reflector is also located on the first side of the substrate. The light reflector comprises a metal structure and a high-k adhesive layer, which may be present on all but one side of the metal structure. A photodiode is also located on the substrate. In particular embodiments, a barrier layer covers the remaining side of the metal structure not covered by the high-k adhesive layer. Methods for making such an image sensor are described in the figures.

The present disclosure also relates in various embodiments to methods for using an image sensor. A signal is sent to a gate structure to open a channel between a photodiode and a floating node. The floating node is then read, and the floating node signal is interpreted. The channel is then closed. The photodiode is then reset.

Some further embodiments of the present disclosure also relate to semiconductor packages that comprise the semiconductor devices disclosed herein, such as image sensors in different embodiments containing the light reflector. Devices including the semiconductor packages or the image sensors described herein containing a light reflector are also disclosed.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for making a semiconductor device, comprising:
forming a trench at least partially located to a first side of a gate structure;
lining the trench with a high-k adhesive layer; and
filling the trench with a metal to form a light reflector.

2. The method of claim 1, wherein the high-k adhesive layer comprises Al₂O₃, TiN, or TaN.

3. The method of claim 1, wherein the high-k adhesive layer has a thickness of about 90 angstroms to about 110 angstroms.

4. The method of claim 1, wherein the metal comprises Cu, AlCu, or W.

5. The method of claim 1, wherein the light reflector has a thickness of greater than zero to about 4000 angstroms.

6. The method of claim 1, wherein the trench extends into an etch stop layer that covers the gate structure.

7. The method of claim 6, wherein the etch stop layer has a thickness of about angstroms or greater.

8. The method of claim 6, wherein the etch stop layer comprises silicon nitride or silicon oxynitride.

9. The method of claim 1, further comprising:
planarizing the substrate; and
forming a barrier layer over the light reflector to reduce metal migration.

10. The method of claim 9, wherein the barrier layer comprises silicon nitride or silicon oxynitride.

11. The method of claim 9, further comprising:
forming an interlayer dielectric (ILD) layer over the barrier layer;
forming a first adhesion layer over the ILD layer;
etching a contact trench off to a second side of the gate structure down to an etch stop layer that covers the gate structure; and
filling the contact trench with a metal.

12. The method of claim 1, wherein the trench extends from the first side of the gate structure and over the gate structure.

13. A semiconductor device, comprising:
a substrate;
a gate structure upon the substrate;
a first dielectric layer over the substrate; and
a light reflector in the first dielectric layer located to one side of the gate structure, the light reflector comprising a metal structure and a high-k adhesive layer.

14. The semiconductor device of claim 13, further comprising:
a first etch stop layer on the substrate and the sides of the gate structure;
and a second etch stop layer that covers the gate structure.

15. The semiconductor device of claim 14, wherein the light reflector extends through the first dielectric layer and into the second etch stop layer.

16. The semiconductor device of claim 13, further comprising a barrier layer that covers the one side of the metal structure of the light reflector not covered by the high-k adhesive layer.

17. The semiconductor device of claim 13, wherein the light reflector extends from the one side of the gate structure and over the gate structure.

18. An image sensor, comprising:
a substrate;
a gate structure on a first side of the substrate;
a light reflector located on the first side of the substrate, the light reflector comprising a metal structure and a high-k adhesive layer on all but one side of the metal structure; and
a photodiode on the substrate.

19. The image sensor of claim 18, further comprising an interconnect layer over the first side of the substrate.

20. The image sensor of claim 18, further comprising at least one light-focusing structure upon the photodiode on the second side of the substrate
